(19) United States
(12) Patent Application Publication
(10) Pub. No.: US 2006/0097129 A1
(43) Pub. Date: May 11, 2006

(54) Lens module structure

(76) Inventors: Kuo-Yang Sun, Kaohsiung City (TW); Chia-Ming Yang, Tainan City (TW); Li-Ju Huang, Tainan City (TW); Juin-Lin Lee, Kaohsiung City (TW); Yi-Jeng Lin, Kaohsiung City (TW)

Correspondence Address: HDSL, 4331 STEVENS BATTLE LANE, FAIRFAX, VA, 22033, US

(21) Appl. No.: 10/984,454

(22) Filed: Nov. 10, 2004

(51) Int. Cl. H01L 27/00; H01J 3/14

(52) U.S. Cl. 250/208.1; 250/216

(57) ABSTRACT

A lens module structure includes an image sensing chip disposed on the first side of a substrate and electrically coupled to the substrate through wires. A memory chip and a control chip are soldered onto a second surface of the substrate, and a solderable output unit terminal is provided on one side of the second surface of the substrate for connecting to other electronic components. A lens pedestal is fastened onto the first surface of the substrate such that the image sensing chip is encapsulated within the lens pedestal, and an optical lens is provided within the lens pedestal and corresponding to the image sensing chip. In such way, the assembled components of the lens are decreased and the chips thereof are designed in a modular mode such that the overall volume of the lens is reduced and the surface mounting technologies can be omitted.

### BACKGROUND OF THE INVENTION

1. Field of the Invention

This invention relates to an improved lens module structure, and in particular, to an improved lens module structure characterized in that the assembled components of the lens module and the overall volume of the lens are reduced.

2. Description of the Prior Art

FIG. 1 is a diagram showing a structure of a conventional lens, which comprises a circuit board 91, a control chip 92, a memory chip 93, an image sensing chip 94 and a lens pedestal 95; wherein the front surface of the substrate has an electric area and the back surface thereof has a plurality of solder ball 97 conducting to the electric area. The control chip 92, the memory chip 93 and the image sensing chip 94 are encapsulated within a package body 96. The package body 96 is soldered onto the electric area on the front surface of the circuit board 91 by means of a surface mounting technology. The lens pedestal 95 is then fastened onto the front surface of the circuit board 91 by using the screws 99 such that the image sensing chip 94 is enclosed by the lens pedestal 95. After the above components are assembled, a conventional lens structure is finished and is able to connect to another control circuit board 98 by the solder balls 97 on the back surface of the substrate 91.

However, since the control chip 92, the memory chip 93 and the image sensing chip 94 are encapsulated within a package body 96, the overall volume of the conventional lens is relatively larger than the respective chips, and all the chips are disposed on the front surface of the substrate 91, such that the finished lens is inevitably huge. Besides, the encapsulating way of package body 96 which uses the surface mounting technology is complicated and should be improved. Further, the assembled lens is soldered on the circuit board 98 by each of the solder balls 97 on the back surface and thus the circuit board 98 is under the whole lens, the packaged lens is soldered onto the control circuit board 98 by the solder balls 97 and thus the substrate 91 on the back surface of the lens is bonded to the circuit board 98 such that the lens occupies much of the volume of the circuit board 98 while connecting thereto. Therefore, it needs a larger board for using as the circuit board 98 connected to the lens.

Accordingly, the above-described prior art product is not a perfect design and has still many disadvantages to be solved.

In views of the above-described disadvantages resulted from the conventional lens, the applicants keep on carving unflaggingly to develop an improved lens module structure according to the present invention through wholehearted experience and research.

### SUMMARY OF THE INVENTION

The present invention is to provide an improved lens module structure in which the assembled components thereof and the overall volume of the lens are reduced.

Furthermore, the invention is to provide an improved lens module structure characterized in that the chips thereof are designed in a modular mode such that the surface mounting technology can be omitted and the manufacturing process is simplified.

The present invention can be achieved by using an improved lens module structure which comprises a substrate, a memory chip, a control chip, an image sensing chip and a lens pedestal; wherein the image sensing chip is fastened to the first surface on the substrate and electrically coupled to the substrate through the wires, an optical lens is disposed within the lens pedestal and bonded to the first surface on the substrate so that the optical lens covers the image sensing chip; besides, the memory and control chips are soldered onto the second surface of the substrate, a solderable output terminal for connecting to other electronic components (such as a circuit board) is disposed at one side of the second surface on the substrate. In such way, the improved lens module structure according to the present invention is finished.

### BRIEF DESCRIPTION OF THE DRAWINGS

The drawings disclose an illustrative embodiment of the present invention which serves to exemplify the various advantages and objects hereof, and are as follows:

FIG. 1 is a schematic cross-sectional diagram that shows a conventional lens;

FIG. 2 is a schematic diagram illustrating an improved lens module structure according to a first embodiment of the present invention;

FIG. 3 is a schematic cross-sectional diagram illustrating an improved lens module structure according to a second embodiment of the present invention;

FIG. 4 is a schematic cross-sectional diagram illustrating an improved lens module structure according to a third embodiment of the present invention; and

FIG. 5 is a schematic diagram that shows a connection between the improved lens module structure in the third embodiment of the present invention and a control circuit board.

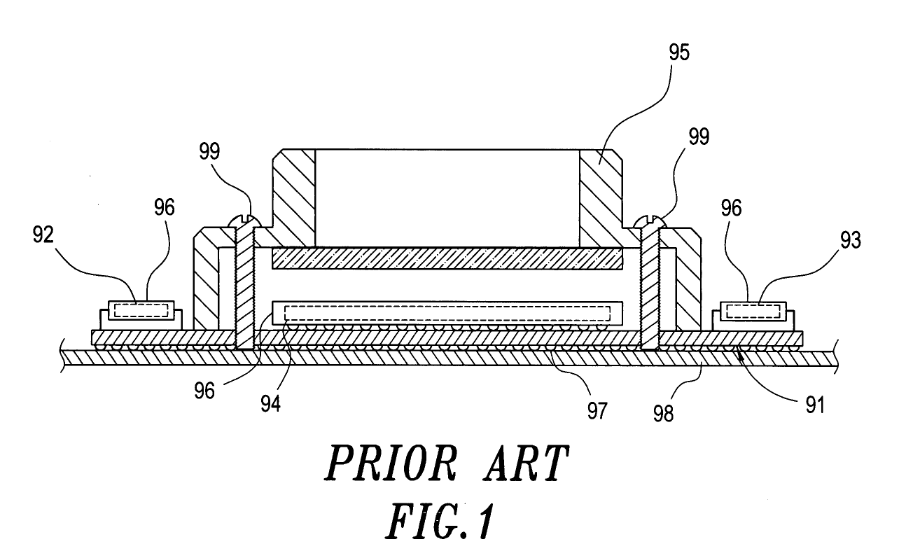

### DETAILED DESCRIPTION OF THE PREFERRED EMBODIMENT

Referring to FIG. 2 through FIG. 4, they are improved lens module structures provided by the present invention, the structures comprise a substrate 1, an image sensing chip 4, a chipset 2, an optical lens 6 and a lens pedestal 5.

The substrate 1 has a first surface 11 and a second surface 12, and a plurality of input terminals (not shown in the drawings) formed thereon. At least one solderable output terminal 121 is disposed at one side of the second surface 12, and the other side of the second surface 12 is not disposed with the solderable output terminal. The input terminal on the second surface electrically couples to the solderable output terminal 121 and electrically couples to the input terminals on the first surface by a plurality of conductive vias (not shown in the drawings) through the substrate 1.

The image sensing chip 4 is fastened on the first surface 11 of the substrate 1 and electrically coupled to the input terminals on the first surface 11 through the wires 41.

The chipset 2 is connected to the second surface 12 of the substrate 1 and electrically coupled to the input terminals of the second surface 12. Referring to FIG. 2, the chipset 2 comprises a memory chip 21 and control chip 22, which are respectively connected to the second surface on the substrate by the flip chip manner so as to electrically couple to the image sensing chip 4 on the first surface 11 of the substrate 1 through the input terminals and conductive vias. Such that, the memory chip 21 and control chip 22 can receive signals from the image sensing chip 4. At the same time, the image sensing chip 4 and chipset 2 can electrically couple to the solderable output terminals 121 on the second surface 12 of the substrate 1.

The cross-section of the lens pedestal 5 is convex and a penetrating aperture 51 is disposed on the centre thereof for assembling the optical lens 6 to the lens pedestal 5 and supporting the optical lens 6 to enclose one end of the penetrating aperture 51.

A layer 7 of gluing substance is uniformly applied on the bottom periphery of the lens pedestal 5 such that the lens pedestal 5 is bonded to the first surface 11 of the substrate 1. The lens pedestal 5 covers the image sensing chip 4 on the first surface 11 of the substrate 1 so that the image sensing chip 4 is corresponding to the penetrating apertures 51 of the lens pedestal 5 for transmitting optical signals to the image sensing chip.

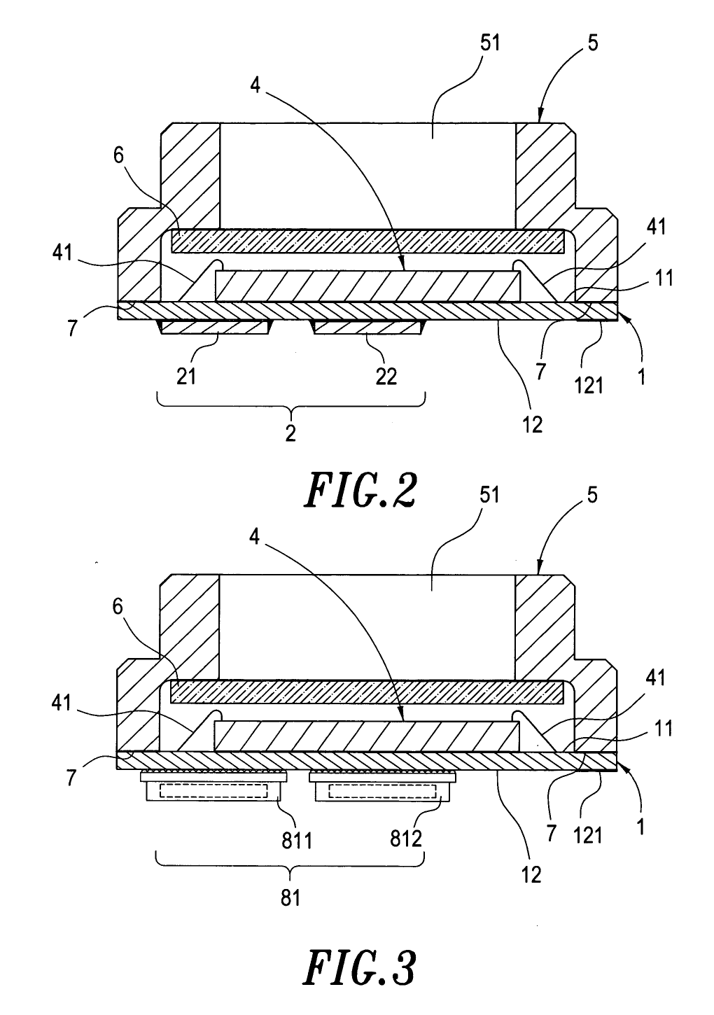

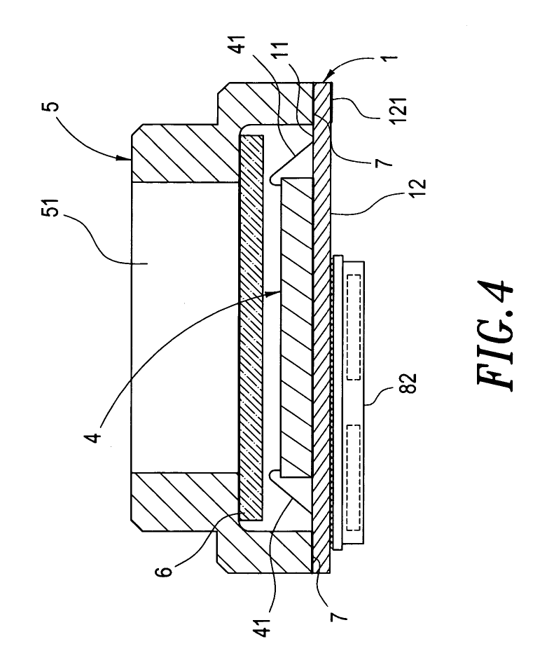

The structure and arrangement of the chipset of the present invention are not limited by the above preferred embodiment but still have another preferred embodiment. Please refer to FIG. 3, which illustrates a second preferred embodiment of the present invention. The chipset 81 is formed of a memory chip 811 and control chip 812, wherein the memory chip 811 and control chip 812 are respectively packaged as a TFBGA package. The chipset 81 is soldered onto the input terminal on the second surface 12 of the substrate 1 by the solder balls for electrically coupling to the image sensing chip 4. Alternatively, referring to a third preferred embodiment shown in FIG. 4, the chipset 82 is an integrated chip with memory and control functions that is formed of a chip having memory and control functions in a packaged body by a TFBGA technology. The chipset 82 is soldered onto the second surface 12 of the substrate 1 by a plurality of solder balls on the back surface of the integrated chip for electrically coupling to the image sensing chip 4. The substrate, optical lens and lens pedestal of the second and third embodiments are the same as those of the first embodiment and thus the description thereto are omitted here.

In each of the lens modules of the above embodiments of the present invention, the chipset 2 of the lens module of the present invention connects to the second surface 12 of the substrate 1 to reduce the volume of the whole module.

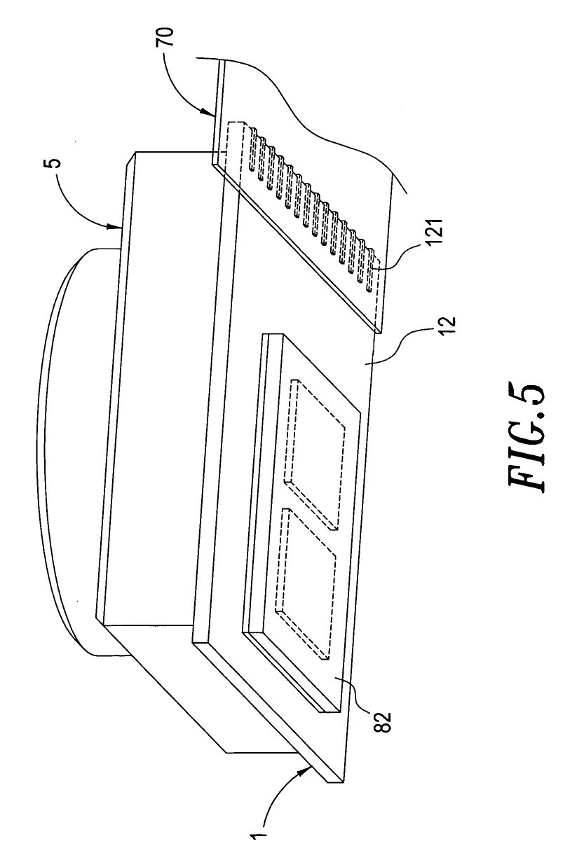

Besides, the arrangement of the present invention on the circuit board is shown in FIG. 5, a schematic diagram that shows a connection between the present invention and the control circuit board 70. The lens module of the present invention is soldered onto the control circuit board 70 by the solderable output terminal 121 on the second surface 12 of the substrate 1 so that a part of the module extends over the circuit board 70 to reduce the space on the circuit board 70 occupied by the lens module. Therefore, the area of the circuit board 70 is reduced and cost of the material is down. The lens module will not occupy the space of the circuit board 70 and thus the area of the circuit board 70 is reduced to achieve the object that reduces the volume of the camera device.

The improved lens module structure of the present invention, when comparing with other previous conventional technologies, has following advantages:

1. The present invention utilizes the substrate to substitute for the circuit board used in the conventional lens such that the first and second sides of the substrate can be connected with chips so as to reduce overall volume of the lens.

2. The image sensing chip of the present invention needs not to be packaged first and then soldered to electrically couple to the first surface of the substrate but uses wires directly connect to the first surface of the substrate, which can reduce the number of the packaged components of the lens and the manufacturing time of the lens. The present invention can also reduce the volume of the finished lens.

3. The present invention assembles chips in a modular mode such that the surface mounting technologies can be omitted so as to provide a simplified production process.

4. The lens module of the present invention is soldered onto the circuit board by the solderable output terminals on a single side of the second surface of the substrate to reduce the occupied space on the circuit board so as to lower the material cost of the circuit board.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A lens module structure comprising:
a substrate comprising a first surface and a second surface with a plurality of input terminals formed thereon, at least one solderable output terminal being disposed at one side of the second surface, wherein the input terminals on the second surface electrically couple to the solderable output terminal and electrically couple to the input terminals on the first surface by at least one conductive via through the substrate;
an image sensing chip fastened on the first surface of the substrate and electrically coupled to the input terminals on the first surface;
a chipset fastened on the second surface of the substrate and electrically coupled to the input terminals of the second surface;
an optical lens; and
a lens pedestal for assembling and supporting the optical lens, adhered to the first surface of the substrate so that the optical lens cover the image sensing chip for sending optical signals to the image sensing chip.

2. The lens module structure according to claim 1, wherein the chipset comprises a memory chip and a control chip, and the memory chip and the control chip are connected to the second surface of the substrate by a flip chip manner.

3. The lens module structure according to claim 1, wherein the chipset comprises a memory chip and a control chip, and the memory chip and the control chip are completely packaged chips.

4. The lens module structure according to claim 1, wherein the chipset is an integrated chip having memory and control functions.

5. The lens module structure according to claim 1, wherein the cross-section of the lens pedestal is convex and a penetrating aperture is disposed through the lens pedestal.

6. The lens module structure according to claim 1, wherein a layer of gluing substance is uniformly applied on the bottom periphery of the lens pedestal such that the lens pedestal is bonded to the first surface of the substrate.
